(19) United States
(12) Patent Application Publication
(10) Pub. No.: US 2025/0363025 A1
(43) Pub. Date: Nov. 27, 2025

(54) FAST CORRELATION RF EXTENSION FOR AUTOMATIC HARDWARE INTERFACE SWITCHING

(71) Applicant: Advantest Corporation, Tokyo (JP)

(72) Inventors: Peter BALUN, San Jose, CA (US); Kosuke MIYAO, San Jose, CA (US); Troy HEISTAND, San Jose, CA (US); Roger McALEENAN, San Jose, CA (US)

(21) Appl. No.: 18/673,501

(22) Filed: May 24, 2024

(51) Int. Cl. G06F 11/263; G06F 11/22

(52) U.S. Cl. CPC G06F 11/263; G06F 11/2205

(57) ABSTRACT

Embodiments of the present invention provide a fast correlation (FASTCO) extension module that can couple various components for device testing and quickly correlate measurements of bench equipment with measurements of ATEs for more accurate and efficient device testing. Moreover, the FASTCO modules disclosed herein allow the same test fixtures and load board to be used by both the ATE and bench equipment, which significantly simplifies the correlation process. Moreover, a high-level programming language can be used to generate commands and data to control the FASTCO modules for routing signals to various components, such as the automated test equipment (ATE), any bench equipment (e.g., a signal generator, spectrum analyzer, etc.), DUTs, etc., and the routing can be managed automatically by the ATE according to a test program, for example.

### FIELD OF THE INVENTION

Embodiments of the present invention relate to the field of device testing. More specifically, embodiments relate to techniques for automatically coupling automated test equipment, bench equipment, or other devices.

### BACKGROUND

A device or equipment under test (DUT) is typically tested to determine the performance and consistency of the device before the device is sold. For example, a DUT can be tested using a large variety of test cases, and the result of the test cases can be compared to an expected output result. When the result of a test case does not match a satisfactory expected value or range of expected values, the device can be considered a failed device or outlier, and the device can be binned based on performance parameters, etc. As is known, a DUT is typically an electronic device.

A DUT is usually tested by automatic or automated test equipment (ATE), or automated test systems (ATS), which may be used to conduct complex testing using software and automation to improve the efficiency of testing. The DUT may be any type of semiconductor device, wafer, or component that is intended to be integrated into a final product, such as a computer, network interface, memory, or other hardware component, such as a solid-state drive (SSD). By removing defective or unsatisfactory chips at manufacture using ATE and ATS, the quality of the yield can be significantly improved.

Testing devices in this way often involves using various pieces of equipment, referred to as bench instruments, which may include spectrum analyzers, signal generators, and the like. Connecting and disconnecting devices to the bench equipment and to the system at various stages of testing are time consuming processes that introduce various wires and connections of different types and sizes, potentially leading to human error and confusion during test setup and configuration. Moreover, the different equipment, wires, and connectors may need to be characterized and de-embedded to ensure the accuracy of testing, which further complicates device testing when using different pieces of bench equipment to test multiple devices.

In order to debug and correlate test results produced by a test system with the results of different pieces of bench equipment, the effect (e.g., losses) of the bench equipment and the wires/connectors thereof must be measured and understood. De-embedding refers to the process of mathematically removing the effects of cables, test fixtures, or other structures from measurement results to accurately characterize the specific DUT. This process is important for ensuring that test measurements reflect the true performance and characteristics of a DUT, without being significantly altered by the characteristics of the connecting cables or fixtures. Accurate de-embedding requires precise characterization so that these influences can be mathematically isolated and eliminated from the measurement data as much as possible.

Correlation refers to the process of ensuring that the measurements and data obtained from RF testing using ATE/ATS systems are consistent with, and can be directly compared to, results obtained from external bench equipment testing. Unfortunately, current approaches to correlation and de-embedding of bench equipment for use with test systems require a time-consuming process that is repeated when a new piece of equipment or wire is used, or whenever a component is disconnected and reconnected to a new load board, for example. Using bench equipment during device testing may involve using different test fixtures and load boards than the test system, which adds further time, cost, and complexity to the testing and correlation process. This is especially true in the case of certain bench equipment that is typically soldered directly to a load board, requiring the use of different load boards at different stages of testing. Switching load boards during device testing is an extremely costly and time-consuming process that greatly reduces testing throughput and efficiency.

The inherent complexities introduced when using external bench equipment for device testing have led to some solutions involving complicated interfaces that utilize switch matrix logic to manually select ports for device testing using different bench equipment, as depicted in FIG. 1 representing a typically commercially available switch matrix 100.

In the example of FIG. 1, exemplary switch circuit 100 can be disposed between a DUT and a test system (e.g., mounted to the front panel of an ATE or placed on top of the ATE) and uses 1-to-4 switches (for instance) to route information bidirectionally between 4 different locations. For example, switch circuit 100 can be used to selectively route 4 different ports of automated test equipment or bench equipment 110 to 4 different device ports 105 for device testing. However, using one or more of these switch circuits significantly increases testing complexity as the switches are typically located in small boxes placed around the existing test equipment, and often require a separate load board and/or socket for connecting to the DUT. Additional cabling is required and is often piled on top of the test equipment with additional mechanical structures added for support, in addition to the new load board and switches, and critical RF paths are routed through and around the modified load board.

Unfortunately, these electrical and mechanical challenges can impact results generated using standard production load boards and sockets, and can skew ATE results away from expected bench results. A more streamlined and automated approach to device testing using bench instruments and automated test equipment with faster and more accurate correlation is desired.

### SUMMARY

Accordingly, embodiments of the present invention provide a fast correlation (FASTCO) extension module that can selectively couple various components for device testing and quickly correlates bench equipment with the ATE for more accurate and efficient device testing. Moreover, the FASTCO modules disclosed herein allow the same test fixtures and load board to be used by both the ATE and bench equipment, which significantly simplifies the correlation and testing process. Moreover, a high-level programming language can be used to generate commands and data to control FASTCO modules for routing signals to various components, such as the automated test equipment (ATE), any bench equipment (e.g., a signal generator, spectrum analyzer, etc.), DUTs, etc. Further, the routing performed by the FATSCO modules can be managed automatically by the ATE according to a test program, for example.

According to one embodiment, an apparatus for selectively coupling devices of a test system is disclosed. The apparatus includes a plurality of switches, and a communication port operable to receive control commands to control the plurality of switches to selectively couple devices of the test system. A first set of the plurality of switches are communicatively coupled to a load board that receives devices under test (DUTs) for device testing.

According to some embodiments, an ATE is operable to control the plurality of switches via the communication port over a communication channel.

According to some embodiments, the first set of the plurality of switches are further operable to selectively couple the load board to the ATE to perform device testing on the DUTs disposed on the load board according to a test program executed by the ATE.

According to some embodiments, the apparatus includes a microcontroller operable to receive the control commands over the communication channel and to control the plurality of switches according to the control commands.

According to some embodiments, the first set of the plurality of switches are further operable to selectively communicatively couple the load board to a bench instrument for bench testing the DUTs when the DUTs are disposed on the load board.

The apparatus of claim 5, the communication port includes Ethernet, and the test program includes a Java test program operable to access a library of external instrument drivers to control the bench instrument over Ethernet.

According to some embodiments, the plurality of switches are operable to be controlled by a test program executed by the ATE, and the test program accesses information that maps pogo pins of the ATE to ports to automatically couple components using the ports to control the switches.

According to some embodiments, the plurality of switches are operable to provide a loop-back communication path for measuring path loss, and the ATE is operable perform an automatic correlation procedure to correlate measurements of the ATE with measurements of bench instruments based on the path loss.

According to some embodiments, the ATE is further operable to automatically verify results of the automatic correlation procedure by coupling the ATE to the bench equipment using the plurality of switches and receiving an input RF signal generated by the bench equipment and measured at the ATE.

According to another disclosed embodiments, a test system for device testing is disclosed. The system includes an automatic test equipment (ATE), a load board including a plurality of sockets, and a radio frequency (RF) extension module including a plurality of switches operable. The RF extension module is operable to receive commands sent by the ATE to control operation of the plurality of switches to couple the ATE to DUTs operable to be disposed in the plurality of sockets for device testing thereof.

According to some embodiments, the RF extension module is further operable to control the plurality of switches to couple the DUTs to bench instruments for testing the DUTs.

According to some embodiments, the RF extension module is further operable to control operation of the plurality of switches to couple the ATE to bench instruments for performing path loss calibration and verification operations.

According to some embodiments, the RF extension module is further operable to control operation of the plurality of switches to provide a loop-back communication path for performing path loss calibration and verification operations of the RF extension module.

According to some embodiments, the RF extension module further includes an Ethernet interface, the RF extension module is operable to receive commands over the Ethernet interface to control operations of the plurality of switches according to a test program that maps pins of the ATE to DUT ports coupled to the load board.

According to a different embodiment, a method of automatic hardware interface switching for device testing using a radio frequency (RF) extension module is disclosed. The method includes receiving a command from an automated test equipment (ATE) to couple a first test system component with a second test system component, controlling operations of a plurality of switches of the RF extension module to couple the first test system component with the second test system component, generating an RF signal using the first test system component, automatically routing the RF signal to the second test system component via the plurality of switches, and measuring the RF signal at the second test system component.

According to some embodiments, the first test system component includes the ATE, and the second test system component includes a load board including a plurality of sockets operable to receive devices under test (DUTs) for device testing thereof by the ATE.

According to some embodiments, the first test system component includes the ATE and the second test system component includes a bench instrument.

According to some embodiments, the ATE is operable to verify path loss calibration between the ATE and the bench instrument by measuring the RF signal generated by the bench instrument at the ATE.

According to some embodiments, the command from the ATE is received by a microcontroller of the RF extension module over Ethernet.

According to some embodiments, the first test system component includes a first device under test (DUT) component, the second test system component includes a second DUT component, and controlling operation of the plurality of switches to form a loop-back path operable to receive the RF signal from the first DUT component and loop the RF signal back for receipt by the second DUT component.

### BRIEF DESCRIPTION OF THE DRAWINGS

The accompanying drawings, which are incorporated in and form a part of this specification, illustrate embodiments of the invention and, together with the description, serve to explain the principles of the invention:

FIG. 1 depicts an exemplary bi-directional RF switching module of the prior art, as discussed above.

FIG. 2 is a block diagram of an exemplary test system that uses a FASTCO module to selectively couple a DUT with an ATE or bench instrument to test or characterize components of the test system according to embodiments of the present invention.

FIG. 3 is a block diagram depicting an exemplary test system that uses a FASTCO module to selectively couple a load board with an ATE or bench instruments for testing multiple DUTs and/or characterizing components of a test system according to embodiments of the present invention.

FIG. 4 is a diagram depicting an exemplary FASTCO module coupled to a load board of an ATE for selectively coupling the ATE to DUTs and/or bench instruments according to embodiments of the present invention.

FIG. 5 depicts an exemplary schematic diagram of an instrument switching module coupling multiple bench ports to 4 inputs of an RF extension module for selective switching to accommodate device testing or characterization/correlation of test components according to embodiments of the present invention.

FIG. 6 depicts an exemplary schematic diagram of an RF extension module coupling 4 ISM inputs to 16 DUT ports for selective switching to accommodate device testing or characterization/correlation of test system components according to embodiments of the present invention.

FIG. 7 is a diagram of an exemplary instrument switching module with trigger inputs disposed in a housing according to embodiments of the present invention.

FIG. 8 is a diagram of an exemplary RF extension module including multiple ATE ports and DUT ports according to embodiments of the present invention.

FIG. 9 is a diagram of an exemplary RF extension module coupled to an exemplary ATE for device testing or characterization/correlation of test system components according to embodiments of the present invention.

FIG. 10 is a block diagram of an exemplary RF extension module performing an automatic 2× loop-back loss measurement process to determine loss associated with an ATE according to embodiments of the present invention.

FIG. 11 is a block diagram of an exemplary RF extension module performing an automatic loss measurement process to determine loss between the RF extension module and an ISM according to embodiments of the present invention.

FIG. 12 is a block diagram of an exemplary RF extension module performing an automatic calibration and verification process according to an RF signal received by an ISM and routed to the RF interface board of an ATE according to embodiments of the present invention.

FIG. 13 is a block diagram of an exemplary RF extension module that receives an RF signal from an RF interface board of an ATE and routes the signal to a measurement instrument for calibration verification according to embodiments of the present invention.

FIG. 14 is a diagram of an exemplary FASTCO programming architecture that includes a test program workspace executed by a computer system that communicates with FASTCO extension module to control the operations thereof according to embodiments of the present invention.

FIG. 15 is a flow chart depicting an exemplary sequence of computer-controlled steps of a process for automatically and selectively coupling test system components (e.g., an ATE or ATS, DUTs disposed in a load board, bench instruments) according to embodiments of the present invention.

FIG. 16 is a flow chart depicting an exemplary sequence of computer-controlled steps of a process for automatically and selectively coupling ports of a load board to ports of an ATE for device testing according to embodiments of the present invention.

FIG. 17 is a flow chart depicting an exemplary sequence of computer-controlled steps of a process for automatically and selectively coupling bench instruments to a DUT for instrument testing according to embodiments of the present invention.

FIG. 18 is a flow chart depicting an exemplary sequence of computer-controlled steps of a process for automatically and selectively coupling bench instruments to characterize or validate signal pathways of a test system according to embodiments of the present invention.

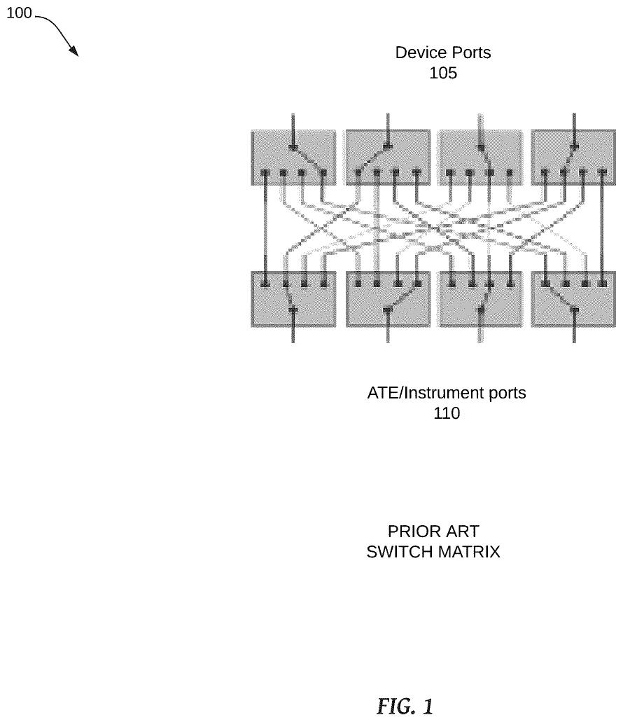

### DETAILED DESCRIPTION

Reference will now be made in detail to several embodiments. While the subject matter will be described in conjunction with the alternative embodiments, it will be understood that they are not intended to limit the claimed subject matter to these embodiments. On the contrary, the claimed subject matter is intended to cover alternative, modifications, and equivalents, which may be included within the spirit and scope of the claimed subject matter as defined by the appended claims.

Furthermore, in the following detailed description, numerous specific details are set forth in order to provide a thorough understanding of the claimed subject matter. However, it will be recognized by one skilled in the art that embodiments may be practiced without these specific details or with equivalents thereof. In other instances, well-known methods, procedures, components, and circuits have not been described in detail as not to unnecessarily obscure aspects and features of the subject matter.

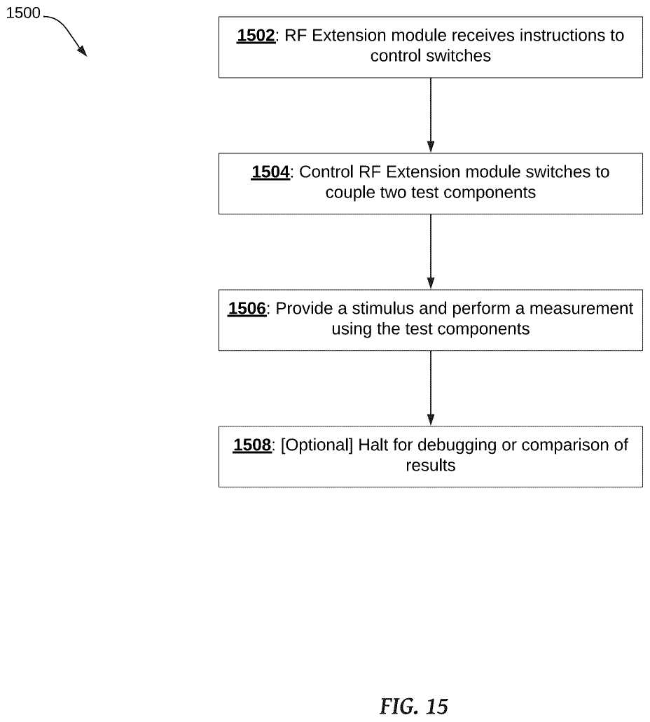

Portions of the detailed description that follows are presented and discussed in terms of a method. Although steps and sequencing thereof are disclosed in a figure (e.g., FIGS. 15-18) herein describing the operations of this method, such steps and sequencing are exemplary. Embodiments are well suited to performing various other steps or variations of the steps recited in the flowchart of the figure herein, and in a sequence other than that depicted and described herein.

Some portions of the detailed description are presented in terms of procedures, steps, logic blocks, processing, and other symbolic representations of operations on data bits that can be performed on computer memory. These descriptions and representations are the means used by those skilled in the data processing arts to most effectively convey the substance of their work to others skilled in the art. A procedure, computer-executed step, logic block, process, etc., is here, and generally, conceived to be a self-consistent sequence of steps or instructions leading to a desired result. The steps are those requiring physical manipulations of physical quantities. Usually, though not necessarily, these quantities take the form of electrical or magnetic signals capable of being stored, transferred, combined, compared, and otherwise manipulated in a computer system. It has proven convenient at times, principally for reasons of common usage, to refer to these signals as bits, values, elements, symbols, characters, terms, numbers, parameters, or the like.

It should be borne in mind, however, that all of these and similar terms are to be associated with the appropriate physical quantities and are merely convenient labels applied to these quantities. Unless specifically stated otherwise as apparent from the following discussions, it is appreciated that throughout, discussions utilizing terms such as “accessing,” “writing,” “including,” “storing,” “transmitting,” “associating,” “identifying,” “encoding,” “labeling,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Some embodiments may be described in the general context of computer-executable instructions, such as program modules, executed by one or more computers or other devices. Generally, program modules include routines, algorithms, programs, objects, components, data structures, etc. that perform particular tasks or implement particular abstract data types. Typically the functionality of the program modules may be combined or distributed as desired in various embodiments.

Fast Correlation Rf Extension for Automatically Coupling Test System with Devices and Bench Instruments

Embodiments of the present invention provide a fast correlation (FASTCO) extension module that can connect various components for device testing and quickly correlate bench equipment measurements with those of the ATE for more accurate and efficient device testing. Moreover, the FASTCO modules disclosed herein allow the same test fixtures and load board to be used by both the ATE and bench equipment, which significantly simplifies the correlation process. Further, a high-level programming language can be used to generate commands and data to control the FASTCO modules for routing signals to various components, such as the automated test equipment (ATE), any bench equipment (e.g., a signal generator, spectrum analyzer, etc.), DUTs, etc., and the routing can be advantageously managed automatically by the ATE according to a test program, for example.

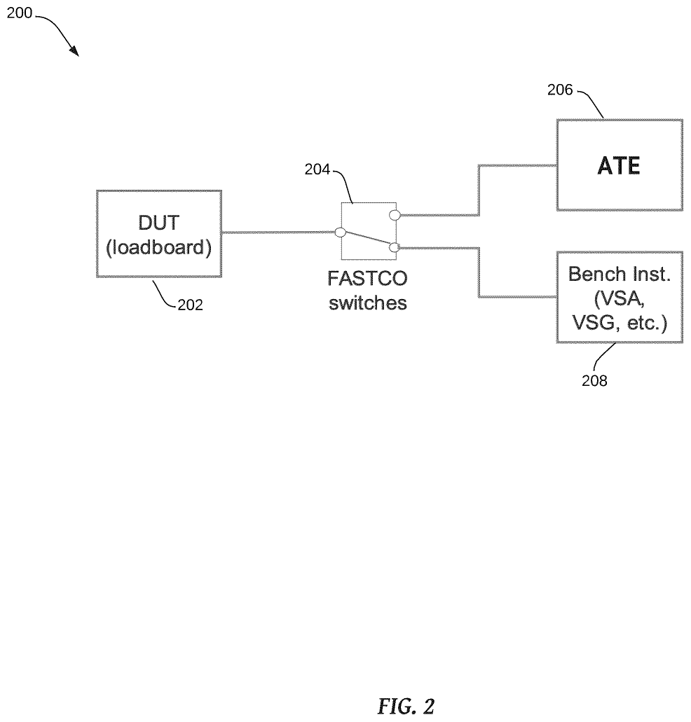

FIG. 2 is a block diagram of an exemplary test system 200 including a FASTCO module 204 used advantageously to selectively couple DUT 202 with ATE 206 or bench instruments 208 to test, characterize, and/or correlate the results of components of test system 200 according to embodiments of the present invention. FASTCO module 204 can include multiple components, with one or more of the components disposed near a load board coupled to ATE 206 that includes a socket for testing DUT 202. Advantageously, test system 200 can selectively couple ATE 206 or bench instruments 208 to DUT 202 for testing without having to change load boards. Additionally, FASTCO module 204 can provide a loop-back path between ATE 206 and bench instruments 208 for automatic path loss measurement of FASTCO components. In this way, FASTCO module 204 significantly improves the speed and accuracy of device testing using automatic device testing and path loss characterization techniques without having to change (e.g., swap in and out) load boards, cables, fasteners, etc.

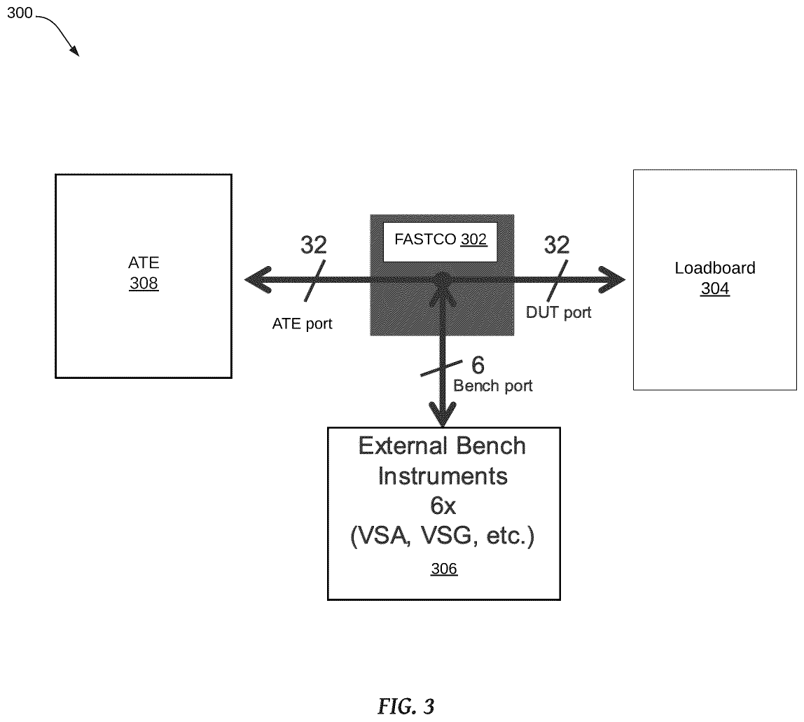

FIG. 3 is a block diagram depicting an exemplary test system 300 including a FASTCO module 302 used advantageously to selectively couple load board 304 with ATE 308 or bench instruments 306 for testing multiple DUTs and characterizing test components of test system 300 according to embodiments of the present invention. In the example of FIG. 3, FASTCO module 302 includes 6 bench ports that can be selectively routed to ports of ATE 308 or load board 304. According to some embodiments, any number of bench ports can be included. The bench instruments can include, for instance, a vector signal generator (VSG), vector signal analyzer (VSA), a spectrum analyzer, frequency generator, etc.

Load board 304 includes 32 DUT ports (in this example) coupled to FASTCO module 302. Load board 304 can include more or fewer DUT ports, according to embodiments. ATE 308 can control FASTCO module 302 (e.g., the internal switches thereof) to automatically couple bench instruments 306 to the DUTs of load board 304 (e.g., in a serial fashion) and can automatically route the signals to another bench instrument to test the DUTs, and so on. In the example of FIG. 3, 32 DUTs can be selectively coupled to one of 6 different bench instruments to instrument test the DUTs, and the DUTs can be decoupled from the bench instruments and coupled to ATE 308 for device testing automatically at any time. The specific number of DUTs and bench instruments given above are exemplary only.

FASTCO module 302 also includes 32 ATE ports (for instance) for communicating with ATE 308, e.g., for automatic RF testing of the DUTs disposed on load board 304, and/or to correlate results of ATE 308 with results of bench instruments 306 to ensure testing accuracy. In the example of FIG. 3, 32 DUTs (for instance) can be selectively coupled in to ATE 308 via FASTCO module 302. FASTCO module 302 can be controlled automatically by a test program to perform automatic hardware interface switching. For example, the ATE can control the FASTCO module 302 to switch between different bench equipment according to a test program, and to automatically stop testing at a designated test point after performing a measurement (e.g., for debugging purposes).

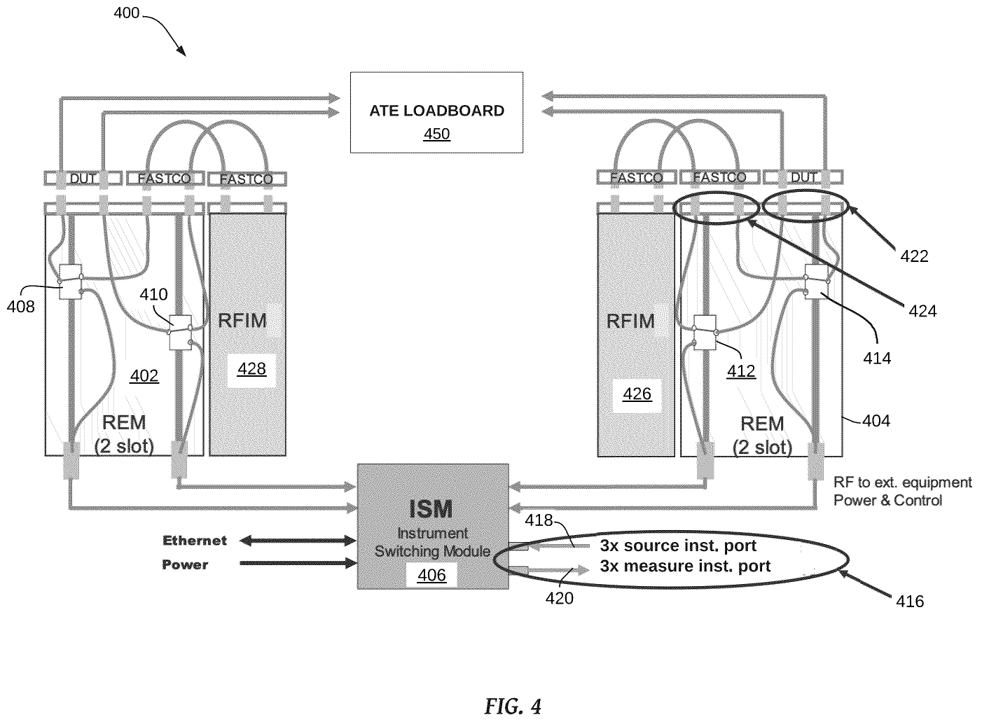

FIG. 4 is a diagram depicting an exemplary FASTCO module 400 coupled to load board 450 of an ATE for selectively coupling the test system components and the DUTs according to embodiments of the present invention. Moreover, FASTCO module 400 includes two remote extension modules (REM) 402, 404 disposed on load board 450, and a separate instrument switching module (ISM) 406 that can communicate with bench instruments coupled to ISM 406 (e.g., via USB or Ethernet).

The ATE can send commands to ISM 406 to control switches 408, 410, 412, 414 of REM 402, 404 to perform hardware interface switching to automatically control the coupling of test components as desired for testing, characterization, debugging, etc. As depicted in FIG. 4, the extension modules 402, 404 can be mirror images of each other and function in the same manner using commands and data generated by the ATE to automatically control internal switches for coupling devices and routing signals as desired (e.g., according to a test program executed by the ATE).

In the example of FIG. 4, ISM 406 provides access to 6 total bench instrument ports 416, including 3 source instrument ports 418 for providing an input RF signal, and 3 measurement instrument ports 420 for measuring an output RF signal. Of course, these specific numbers of bench instrument ports above are exemplary. Advantageously, the instruments connected to bench instrument ports 416 can be coupled to the ATE or to individual DUTs disposed on load board 450 by configuring switches 408, 410, 412, 414 without changing the load board, which significantly improves testing efficiency and accuracy. Moreover, separate procedures to de-embed components can be avoided as the components can remain in place regardless of which components are in-use during testing.

Extension module 404 includes DUT ports 422 that can connect the ATE to individual DUTs disposed on load board 450 of the ATE so that device testing can be performed by the ATE. In this example, RF extension modules 402, 404 can be used to selectively connect to 16 DUTs, for instance. FASTCO ATE ports 424 couple REM 404 to RF interface module (RFIM) 426 of the ATE and similarly REM 402 is coupled to RFIM 428. Switches 408, 410, 412, 414 can be configured to connect RFIM 426 to DUTs disposed on load board 450 of the ATE via ports 422, 424 perform testing operations on the DUTs using the ATE without changing load board 450 or running long cables which may need to be characterized prior to testing. Moreover, switches 408, 410, 412, 414 of REMs 402, 404 can be controlled automatically by the ATE according to a test program, for example, and the test program can switch seamlessly between the ATE and the bench instruments during testing of the DUTs.

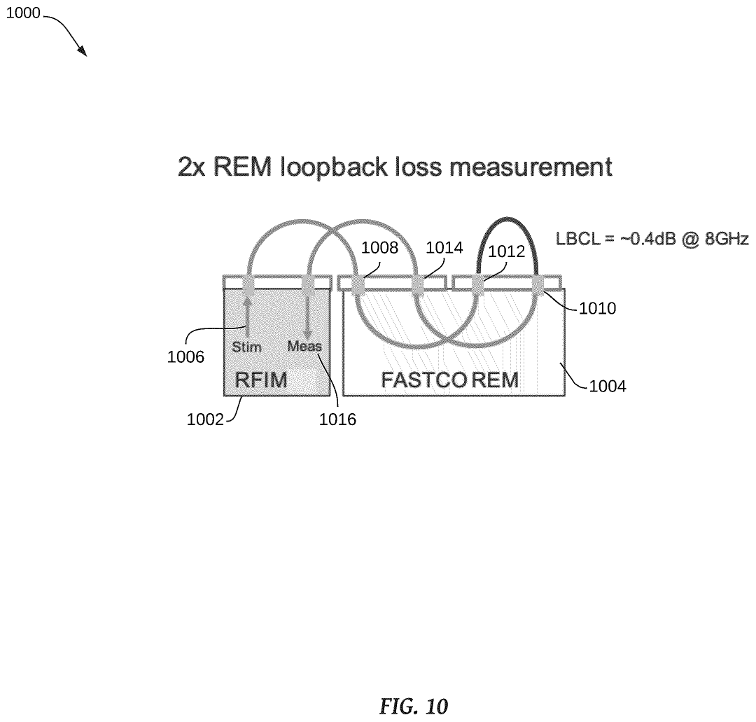

The embodiment depicted in FIG. 4 is further operable to perform loop-back testing for validation of signal paths via diagnostic controls and settings of ISM 406 and the external bench equipment. For example, a signal generator can be coupled to a source instrument port 418 and the signal can be routed to RF interface module 426 to characterize the path between ISM 406 and RF interface module 426. More details regarding characterization and validation procedures between the ATE, the ISM, and REMs are described below with respect to FIGS. 10-13 according to other embodiments of the present invention.

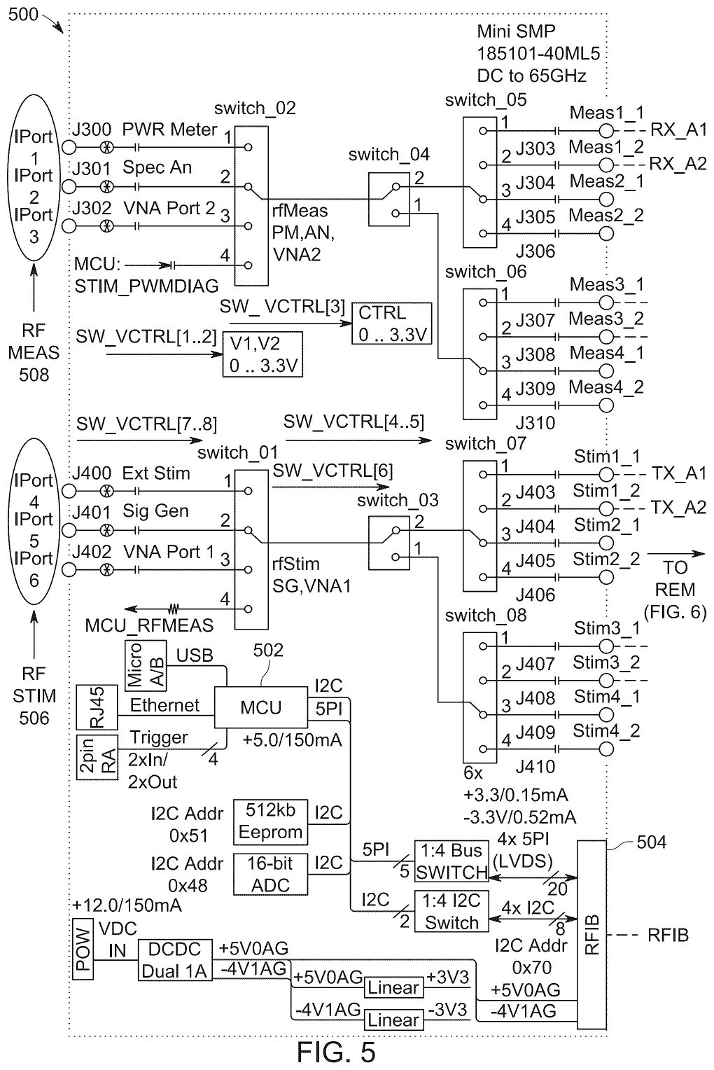

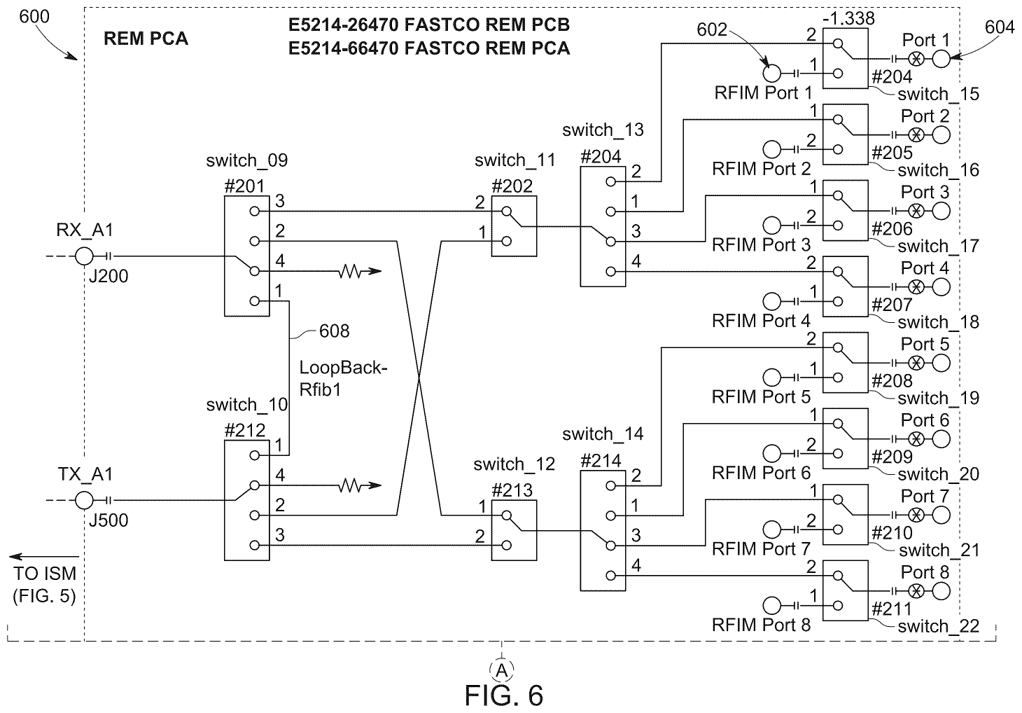

FIG. 5 is a schematic diagram of an exemplary ISM 500 for automatic selective switching to accommodate device testing or characterization/correlation of test system components according to embodiments of the present invention. The left side of ISM 500 includes 6 bench ports (for instance) IPort 1, IPort 2, IPort 3, IPort 4, IPort 5, IPort 6 for coupling with various bench instruments for devices testing and/or correlation purposes. The bench ports are routed through multiple controllable switches (e.g., ADRF semiconductor chips) to route the signal pathways during testing as desired. The signal pathways depicted in FIG. 5 are bidirectional. Different numbers of bench ports can be considered.

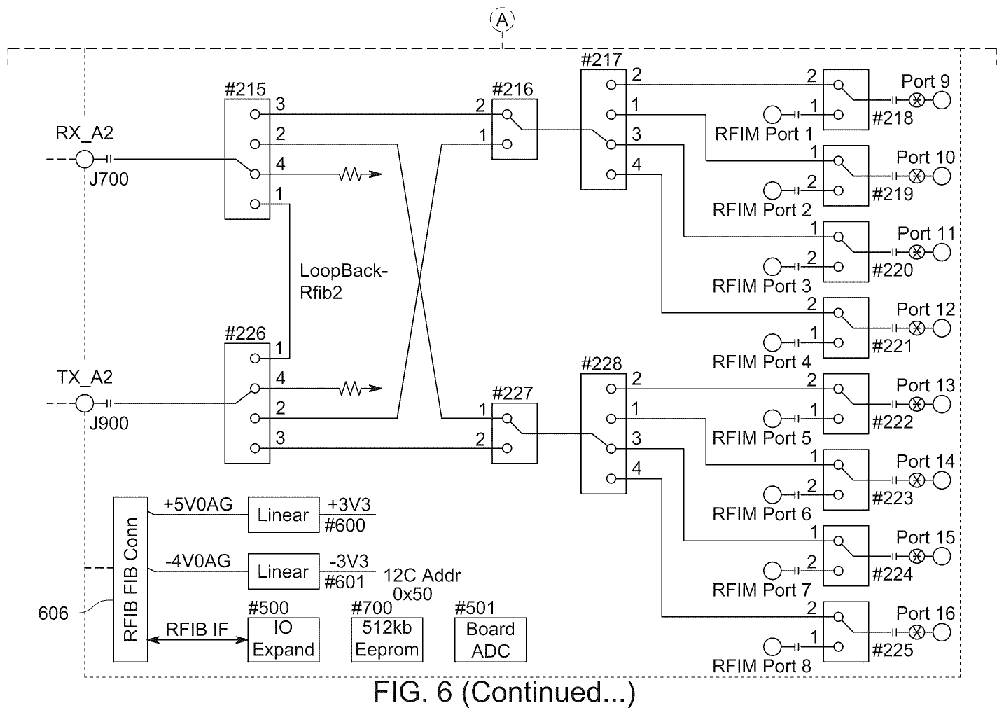

In the example of FIG. 5, RF signal inputs (stim) 506 are coupled to 4:1 switch_01, and RF signal outputs (meas) 508 are coupled to 4:1 switch_02. Ports of switch_01, switch_02 are coupled to 1:2 switches switch_03, switch_04 respectively. Ports of switch_03, switch_04 are coupled to 1:4 switches switch_05, switch_06, and switch_07, switch_08, respectively, and these switches can be coupled to 16 total ports (for instance) to interface with REM 600 as depicted in FIG. 6. In this way, the switches of ISM 500 can be automatically toggled so that bench instruments coupled to bench ports IPort 1, IPort 2, IPort 3, IPort 4, IPort 5, IPort 6 can be selectively coupled to ports of REM 600. REM 600 can further route these pathways to an ATE or to DUTs disposed on a load board for device testing or path loss characterization, for example. In the example of FIG. 5, two measurement paths RX_A1, RX_A2 and two stimulus paths TX_A1, TX_A2 are routed to REM 600.

ISM 500 includes a processor 502 (e.g., a microcontroller (MCU)) and a LAN or USB interface communicating with RF interface board (RFIB) 504. RFIB 504 communicates with an RFIB FIB module of an REM (e.g., RFIB FIB module 606 of REM 600 of FIG. 6) to control the REM 600 (e.g., to control switches of the REM) for routing RF signals as desired during testing/characterization. For example, the switches of ISM 500 and REM 600 can be automatically controlled by the MCU according to a test program executed by an ATE in communication with ISM 500. ISM 500 can communicate with the ATE over any connection type but can be a wired connection, such as USB, Ethernet, etc. RFIB 504 is also responsible for performing power supply, diagnostics, monitoring, and housekeeping functions of ISM 500 and the REM, according to embodiments.

FIG. 6 is a schematic diagram of an exemplary REM 600 (as discussed above) for automatic selective switching to accommodate device testing or characterization/correlation of test system components according to embodiments of the present invention. The left side of REM 600 includes 4 ports coupled to signal paths RX_A1, RX_A2, TX_A1, TX_A2 of an instrument switching module (e.g., ISM 500) to selectively couple bench instruments with a DUT for device testing, or with an ATE to determine path loss information or to verify compensation factors of test system components. The signal paths depicted in FIG. 6 are bidirectional, and the number of ports discussed above is exemplary.

In the example of FIG. 6, RX_A1 or TX_A1 ports can be selectively coupled to RFIM ports 1-8 and DUT ports 1-8 by controlling switch_09, switch_10, switch_11, switch_12, switch_13, switch_14. In general, ports RX_A1, RX_A2 receive signals from an instrument that generates an RF output signal (stim), and ports TX_A1, TX_A2 transmit signals to an instrument that receives an RF input signal (e.g., for measurement).

Switch_13 is a 1:4 switch that selectively couples RX_A1 or TX_A1 to RFIM/DUT ports 1-4. Similarly, Switch_14 selectively couples RX_A1 or TX_A1 to RFIM/DUT ports 5-8. In this way, bench instruments coupled to ISM ports RX_A1, TX_A1 can be coupled to RFIM/DUT ports 1-8 automatically during testing without having to run wires or change load boards, which significantly reduces testing costs and improves testing efficiency.

Switch_09, switch_10 can be configured to provide: a loop-back path 608 when both switches are configured in position 1; DUT/ATE coupling when configured in positions 2-3; and ground or ‘off’ in position 4. Switch_09 and switch_10 are both selectively coupled to switch_13 and switch_14 via switch_11 and switch_12. Switch_15, switch_16, switch_17, switch_18, switch_19, switch_20, switch_21, switch_22, can be configured to couple switch_13, switch_14 to a corresponding RFIM port or DUT port. For example, switch_16 can selectively couple switch_13 to either RFIM port 1 (602) or DUT port 1 (604), and so on.

RX_A2 and TX_A2 can be selectively coupled to RFIM ports 9-16 or DUT ports 9-16 using internal switches controlled by ISM 500 in the same way as described above with respect to RFIM ports 1-8 and DUT ports 1-8.

RFIB FIB module 606 communicates with an RFIB (e.g., RFIB 504 of ISM 500 of FIG. 6) to receive control commands from an ISM (e.g., to control switches of the REM) for routing RF signals as desired during testing/characterization, and for other housekeeping operations, power control, etc.

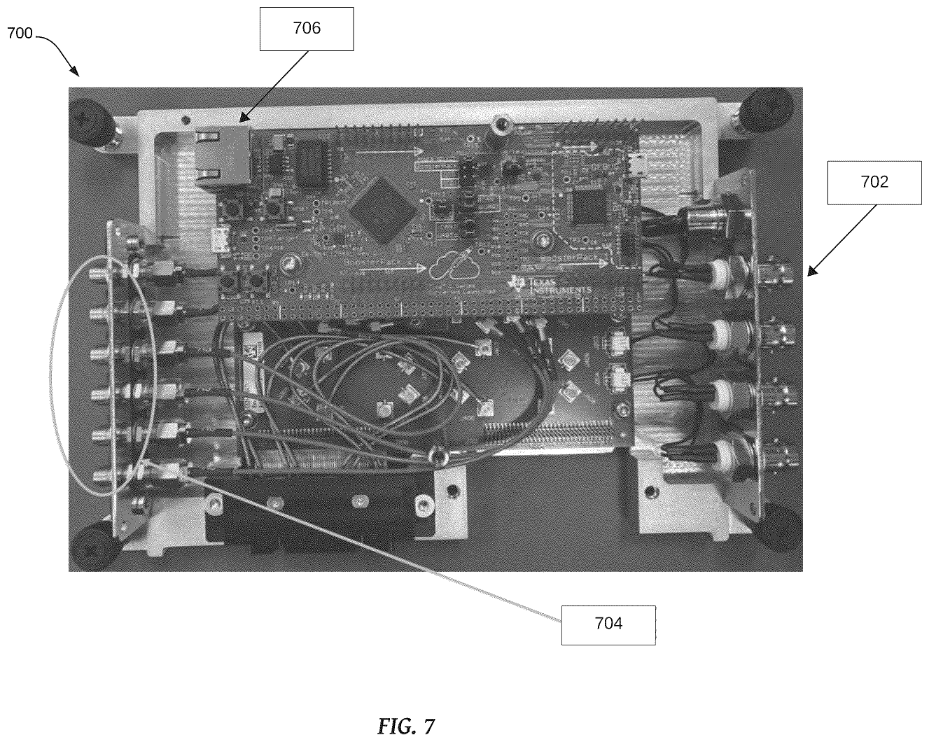

FIG. 7 is a diagram of an exemplary instrument switching module 700 with trigger inputs 702 and bench ports 704 disposed in housing 706 according to embodiments of the present invention. ISM 700 can advantageously selectively route signals between bench instruments coupled to bench ports 704 and remote extension modules of a FASTCO module for device testing, and the bench instruments can be activated or controlled according to trigger signals 702 transmitted to the bench instruments by ISM 700. For example, trigger signals 702 can be provided to bench instruments via ISM 700 to initiate an RF measurement or activate an input RF signal. In this way, multiple bench instruments can be controlled and coupled according to a test program for device testing, path characterization, correlation, and the like. ISM 700 can be controlled via network interface 706.

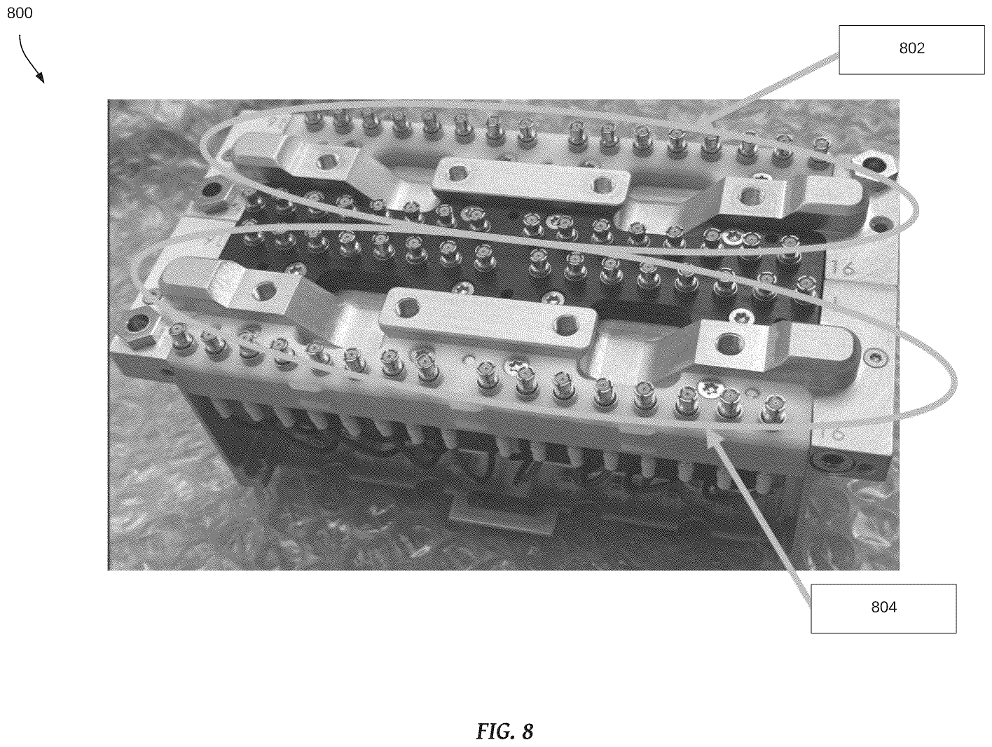

FIG. 8 is a diagram of an exemplary RF extension module 800 of a FASTCO module including ATE ports 802 and DUT ports 804 for selective coupling the ATE to DUTs disposed on a load board according to embodiments of the present invention. ATE ports 802 can be coupled to RFIM interfaces (e.g., pogo pads or pins) of an ATE, and the FASTCO module can be controlled to map the RFIM interfaces to a specific REM and ATE port 802 thereof. DUT ports 804 can be coupled to the ATE load board and can route signals to/from DUTs disposed in sockets of the load board.

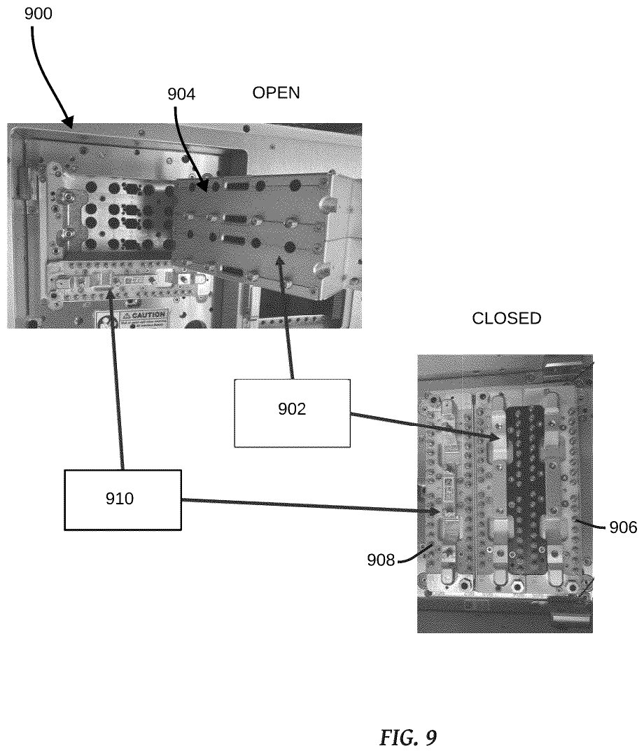

FIG. 9 is a diagram of an exemplary RF extension module (REM) 902 disposed in an ATE 900 for device testing, characterization, and/or correlation of test system components according to embodiments of the present invention. FIG. 9 shows REM 902 separate from ATE 900 (OPEN) and also coupled to ATE 900 (CLOSED) so that the different components of REM 902 can be viewed. Specifically, in the closed state, REM 902 is inserted into an opening of ATE 900 (e.g., in a test head of ATE 900 below the load board) designed to accommodate pogo interfaces of REM 902 for coupling ISM ports 904 to a separate instrument switching module. REM 902 is disposed in close proximity to RFIM 910 of ATE 900, and can be coupled to RFIM 910 using one or more cables for sending signals between ATE 900 and REM 902. The bottom side of RF extension module 902 includes DUT ports 906 and ATE ports 908 as described above with regard to FIG. 8. In this way, RF extension module can be securely coupled with the ATE, DUTs, and can be coupled to ISM 912 for interfacing with bench instruments. Any cables used to couple ports 904, 906, 908 can be characterized/de-embedded initially and can then remain in place throughout testing, which significantly reduces complexity when coupling various components and allows testing to be completed using a single load board.

### Novel Fast Correlation Rf Extension Path Loss Compensation and Validation Techniques

Embodiments of the present invention can correlate and validation test system components and configurations thereof automatically using the described FASTCO extension module controller by a computer system or ATE. Specifically, the signal paths between the REM and the ATE disposed in the load board (FRL) and between the bench instruments and ports of the REM module (FIL) can be determined and compensated for during device testing. The FIL and FRL compensation factors can be validated by providing an RF input signal (stim) to the REM and by measuring the stim at the RFIM. De-embedding the signal pathways in this way significantly improves the accuracy of device measurements.

FIG. 10 is a block diagram of an exemplary RFIM 1002 configured to perform an automatic 2× loop-back loss measurement process coordinated with FASTCO REM 1004 for improved device testing according to embodiments of the present invention. The loss measurement process can determine characteristics of test system components so that these characteristics can be factored into device testing to ensure accurate and reliable device testing results. In the example of FIG. 10, an RF output signal (stim) 1006 is transmitted by RFIM 1002 to an ATE port 1008 of FASTCO REM 1004 and then loops back via REM 1004 through DUT port 1010 to DUT port 1012. The signal is then routed out through ATE port 1014. Port 1014 is coupled to measurement RF input port 1016 for measurement to characterize the path taken by the signal referred to as the FASTCO RFIM loss (FRL). The FRL is equal to half the difference between the measurement taken at port 1016 and the stimulus 1006 provided at port 1006 minus any load board loss (LBCL) according to the equation:

$$FRL = ( ( Meas - Stim ) LBCL ) / 2 dB$$

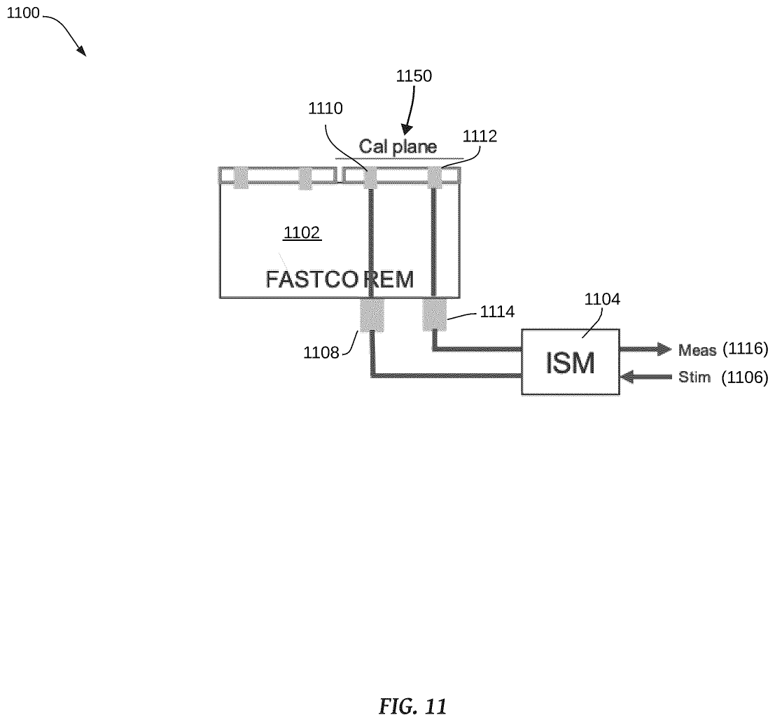

FIG. 11 is a block diagram of an exemplary REM 1102 configured to perform an automatic loss measurement process to determine loss between REM 1102 and ISM 1104 for improved device testing according to embodiments of the present invention. In the example of FIG. 11, an RF output signal (stim) 1106 is received by ISM 1104 and routed to ISM port 1108 of REM 1102. REM 1102 routes the signal out of DUT port 1110 and the signal is looped back as input to DUT port 1112 and provided to ISM port 1114 for routing back to ISM 1104. Stim 1106 and the measurement (meas) 1116 at ISM 1104 can be performed by bench instruments coupled to bench ports of SIGM 1104. For example, stim 1106 can be generated by a signal generator coupled to ISM 1104, and the loop-back measurement can be performed by a signal analyzer coupled to ISM 1104. In FIG. 11, the signal path beyond the calibration plane (cal plane 1150) is typically not characterized. Accordingly, the loss (FIL) between FASTCO ISM 1104 and FASTCO REM 1102 before the cal plane can be calculated as:

$$FIL = Stim @ cal plane - Stim ; \\ FIL = Meas - Meas @ cal plane$$

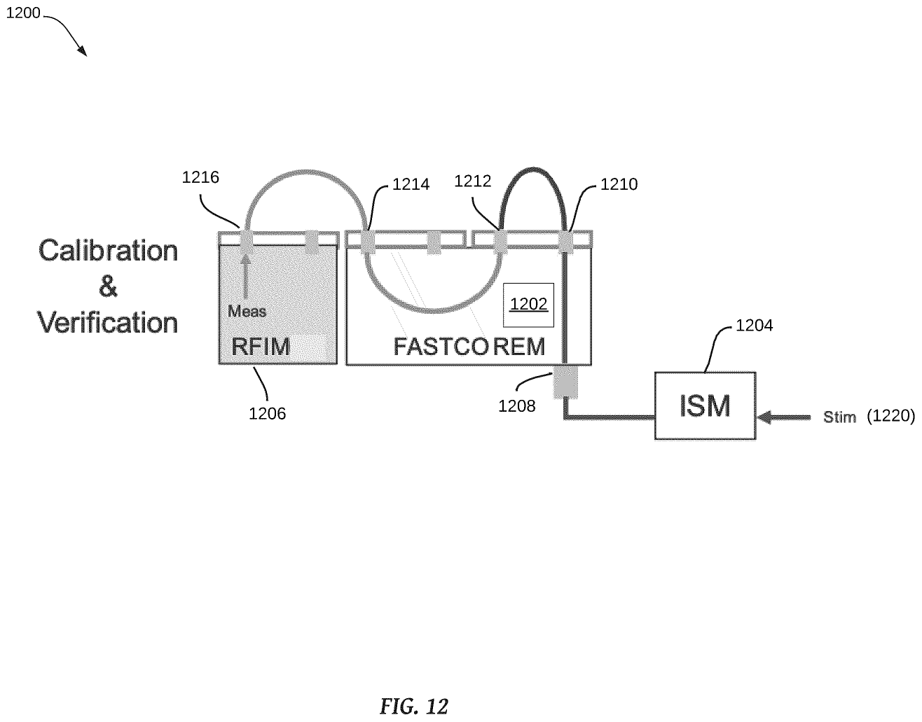

FIG. 12 is a block diagram of an exemplary REM 1202 performing an automatic verification process according to an RF signal (stim) 1220 received by ISM 1204 and routed to RFIM 1206 according to embodiments of the present invention. In the example of FIG. 12, the FIL+FRL path loss is verified by comparing the input stim 1220 received by ISM 1204 to the measurement at RFIM 1206. For example, as depicted in FIG. 12, an input stim 1220 can be generated by a signal generator or other bench instrument coupled to an instrument port of ISM 1204 and then routed to ISM port 1208 of REM 1202. The signal is looped back via DUT ports 1210, 1212 and passed through ATE port 1214 to RFIM 1206 where the signal is measured by an ATE via port 1216 of RFIM 1206. The difference between stim 1220 and the measurement at 1216 indicates the signal error. The signal error can be calculated as:

$$StimPower = StimPower + FIL \\ measPower = measPower \cdot get ( site ) + FRL \\ MeasError = measPower - StimPower$$

In the equation above, measPower.get(site) refers to the actual signal measurement performed at the specific port of RFIM 1206, and measPower is the measurement adjusted for FASTCO RFIM loss (FRL). The verification process depicted in FIG. 12 can be repeated for each of the 16 ATE ports (for instance) of the RFIM 1206, where each ATE port measures the stim 1220 provided via REM 1202 and generated by a bench instrument (e.g., a signal generator (not shown)) coupled to ISM 1204.

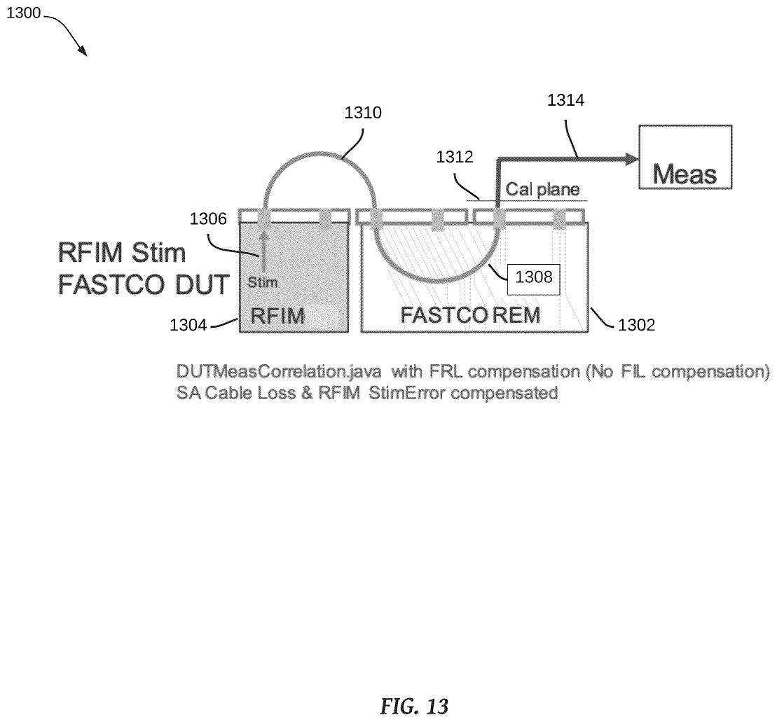

FIG. 13 is a block diagram of an exemplary REM 1302 configured to receive an RF input signal (stim) 1306 from RFIM 1304 and to route signal 1306 to DUT port 1308 to verify the FASTCO RFIM loss (FRL) calibration (without FIL compensation) according to embodiments of the present invention. Stim 1306 is routed from ATE port 1310 to DUT port 1308 and measured beyond calibration plane 1312. It is appreciated that the cable loss beyond calibration plane 1312 can be compensated for using cables of known characteristics or using a separate compensation process. The RF output 1314 is measured and compared to stim 1306 to validate any applied compensation factors (e.g., cable loss, FRL, RFIM stim error) with a high degree of accuracy (e.g., within +/−1 dB of uncertainty).

### Fast Correlation RF Extension Programming Architecture

Some embodiments of the present invention include executing a test program that accesses code, scripts, packages, routines, libraries, etc., for interfacing with a FASTCO extension module to coordinate and control the operations thereof for efficient device testing. The testing can include performing correlation procedures and verifying the compensation factors thereof. Some embodiments include accessing bench instrument library functions and drivers for interfacing with bench instruments coupled to an ISM of the FASTCO module. Some embodiments include accessing a library of functions that interface with the FASTCO module.

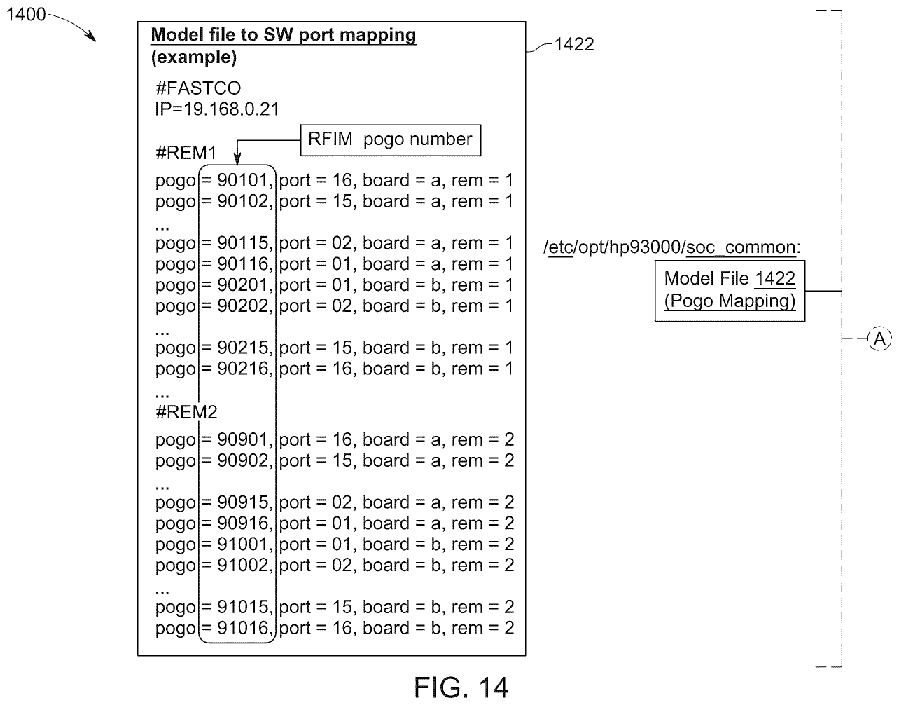

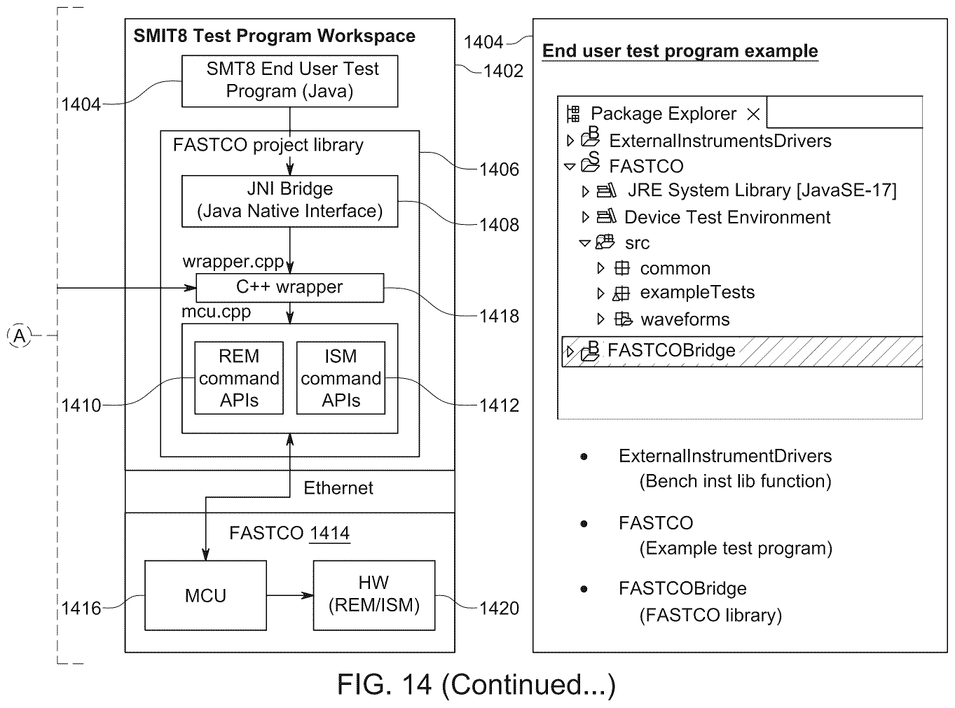

FIG. 14 is a diagram of an exemplary FASTCO programming architecture 1400 that includes a test program workspace 1402 executed by a computer system that communicates with FASTCO extension module 1414 via ethernet (for instance) to control the operations thereof according to embodiments of the present invention. In the example of FIG. 14, workspace 1402 is used to develop end user test program 1404 in Java (for instance) using FASTCO project library 1406, which uses Java Native Interface 1408 to interface with a C++ wrapper 1418 for communication with the FASTCO extension module 1414 via APIs including REM commands 1410 and ISM commands 1412. Of course, other suitable languages can be used. The APIs can communicate with a microcontroller (MCU) 1416 of FASTCO extension module 1414 to control hardware 1420 (e.g., switches, triggers, etc.). In this way, automatic hardware interface switching can be performed so that devices coupled to FASTCO extension module 1414 can be selectively coupled to other components of the test system (e.g., ATE or load board) by the end user according to test program workspace 1402, e.g., during device testing, characterization, etc.

According to some embodiments, C++ wrapper 1418 communicates with FASTCO extension module 1414 according to model file 1422 that maps RFIM pogo pins to ports used to communicate with various bench instruments or the DUTs disposed in sockets of the load board according to the ports. The test system executing exemplary test program 1404 communicates with FASTCO module 1414 via Ethernet (for instance) and can be assigned a static IP. The different REMs of FASTCO module 1414 are assigned a number and a board. A FASTCO module typically includes 2 REMs (1, 2) each having 2 boards (a, b), although other configures having different numbers of REMs and/or boards are contemplated within the scope of the present invention. The ports are used in combination with the REM number (e.g., 1 or 2) and board identifying (e.g., a or b) to couple specific ATE pogo interfaces (e.g., interfaces of the FRIM) to a specific DUT port or instrument port.

End user test program 1404 accesses various libraries and drivers for issuing commands to FASTCO module 1414 to control the hardware 1420 (e.g., switches, triggers) thereof. According to some embodiments, FASTCO module 1414 is recognized as an instrument by the ATE and can be interfaced with and configured accordingly.

Table I below shows an exemplary API for interfacing with a FASTCO extension module to coordinate and control the operations thereof using inputs “pogoNumber” and “connection” according to embodiments of the present invention. The API can be used to connect specific RFIM pogo pins to a bench instrument port or to the ATE. In this example, a value between 1 and 6 corresponds to 6 external instrument ports respectively. A value of 0 restores the pogo connection to the ATE, for example.

TABLE 1
Input Parameters
int pogoNumber
int connection
Output Parameters
None
Returns
int status
Overloads
int fastcoConnect(int pogoNumber, int connection);
C++ Wrapper Function Calls
fastcoConnect(int pogoNumber, int connection);
C++ MCU Driver Function Calls
int hwRemPortConnect(int sockfd, int sectionNumber, int portNumber,
int remModuleNumber, char* msg_sent, char* mcu_reply);
Called if connection = 1 to 6
int hwlsmlnstConnect(int sockfd, int instNumber, int
remModuleNumber, int sectionNumber, char* msg_sent, char*
mcu_reply);
Called if connection = 1 to 6
int hwRemPortRfim(int sockfd, int portNumber, int
remModuleNumber, char* msg_sent, char* mcu_reply);
Called if connection = 0

As shown in Table 1, FASTCO RF extension modules can be controlled by issuing commands according to C++ function calls according to the port number, pogo number, remModuleNumber, and other variables relating to the operation of the extension module. Of course, any suitable programming language could be used. The C++ wrapper executing the functions typically communicates with FASTCO extension module according to model file that maps RFIM pogo pins to specific ports which significantly reduces testing complexity as the ports can be connected automatically by the FASTCO module instead of manually swapping wires, load boards, etc. Furthermore, the ports can be mapped automatically by the test program rather according to a model file or the like, rather than requiring manual modification of switch matrices, etc.

### Novel Methods of Device Testing and Path Loss Compensation Using Fast Correlation RF Extension Module

Embodiments of the present invention provide novel methods of computer-controlled hardware interface switching operations to automatically couple signal pathways used for device testing, path characterization, etc., for improved testing accuracy and efficiency while significantly reducing costs. The methods described herein avoid the need for separate load boards or running long wires to various components that may need to be changed or compensated for during testing.

FIG. 15 is a flow chart depicting an exemplary sequence of computer-controlled steps of a process 1500 for hardware interface switching for selective coupling of test system components (e.g., an ATE or ATS, DUTs disposed in a load board, bench instruments) according to embodiments of the present invention.

At step 1502, an RF extension module (e.g., a FASTCO module) receives instructions to perform a hardware switching operation to control the operation of one or more switches thereof. For example, step 1502 can include receiving instructions at an ISM of the FASTCO module from a test system over a communication channel (e.g., an Ethernet connection).

At step 1504, the switch or switches of the FASTCO module is/are controlled to couple two test system components together over a bi-directional path to enable a signal to propagate between the components.

At step 1506, a stimulus is provided by one of the components and propagates to the other component where it can be measured. Step 1506 can be performed as part of a test program executing by an ATE or ATS to test a device or to correlate test system components based on characteristics thereof (e.g., loss).

At step 1508, the test program optionally halts at a designated break point and debugging can be performed or results can be analyzed/compared before the test program continues.

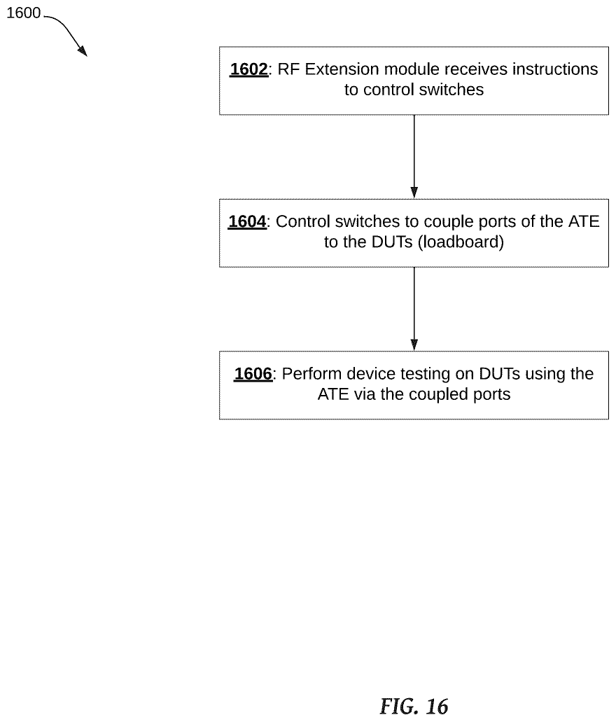

FIG. 16 is a flow chart depicting an exemplary sequence of computer-controlled steps of a process 1600 for automatically and selectively coupling ports of a load board to ports of an ATE for device testing according to embodiments of the present invention.

The steps of process 1600 can incorporate compensation factors according to characteristics of signal pathways used to couple components. The compensation factors can be determined automatically by the ATE, for example.

At step 1602, an RF extension module (e.g., a FASTCO module) receives a command to perform a hardware interface switching operation including controlling the operation of one or more switches of the RF extension module to couple two components. For example, step 1602 can include receiving instructions at an ISM of the FASTCO module from a test system over an Ethernet connection, for instance.

At step 1604, the switch or switches of the FASTCO module is/are controlled to communicatively couple ports of the ATE (e.g., RFIM ports) and ports of the load board (DUT ports) together in to enable a signal to propagate between the components according to the command received in step 1602.

At step 1606, the ATE performs device testing on DUTs disposed in the load board via the RF extension module.

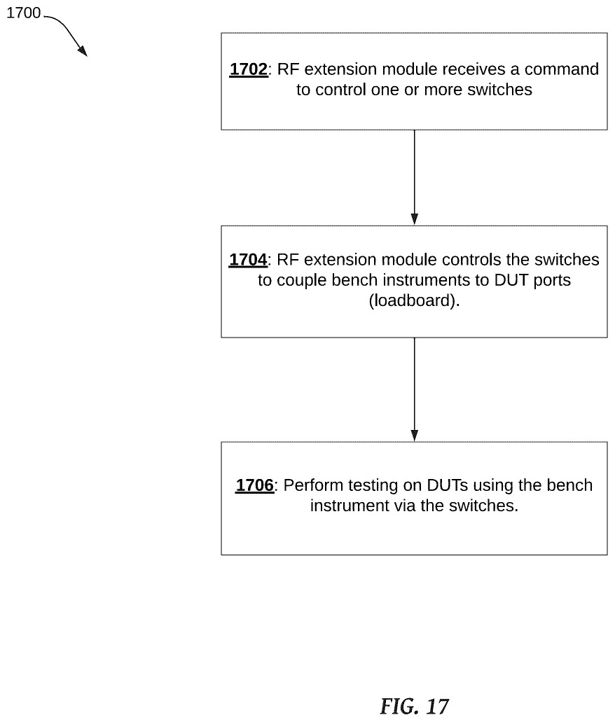

FIG. 17 is a flow chart depicting an exemplary sequence of computer-controlled steps of a process 1700 for automatically and selectively coupling bench instruments to a DUT for instrument testing according to embodiments of the present invention. The instrument can be for instance a vector signal generator, vector signal analyzer, spectrum analyzer, frequency generator, or any other instrument suitable for RF testing purposes. Process 1700 can be performed automatically during device testing. For example, process 1700 can be performed while device testing is being performed by the ATE using process 1600 according to the test program. In other words, embodiments can automatically switch between process 1600 (ATE device testing) and process 1700 (bench testing) on the fly.

The steps of process 1700 can incorporate compensation factors according to characteristics of signal pathways used to couple components. The compensation factors can be determined automatically by the ATE, for example.

At step 1702, an RF extension module (e.g., a FASTCO module) receives a command to perform a hardware interface switching operation to control the operation of one or more switches thereof. For example, step 1702 can include receiving instructions at an ISM of the RF extension module from a test system over ethernet, and the ISM can control switches internal to the RF extension module (e.g., switches disposed in the ISM or REM of the RF extension module).

At step 1704, the switch or switches of the FASTCO module is/are controlled to communicatively couple ports of the bench instruments with ports of the load board (DUT ports) together to enable a signal to propagate between the components.

At step 1706, the DUTs disposed on the load board are tested by the bench instrument. Steps 1704, 1706 can be repeated according to the test program to couple the DUTs to different bench instruments for further testing. Step 1706 can further include transmitting a trigger signal (e.g., sequenced manual triggering) from the ISM to the bench instrument to control the bench instrument during testing. The trigger signals can be defined in the test program and can be generated automatically by the ATE during testing, for example.

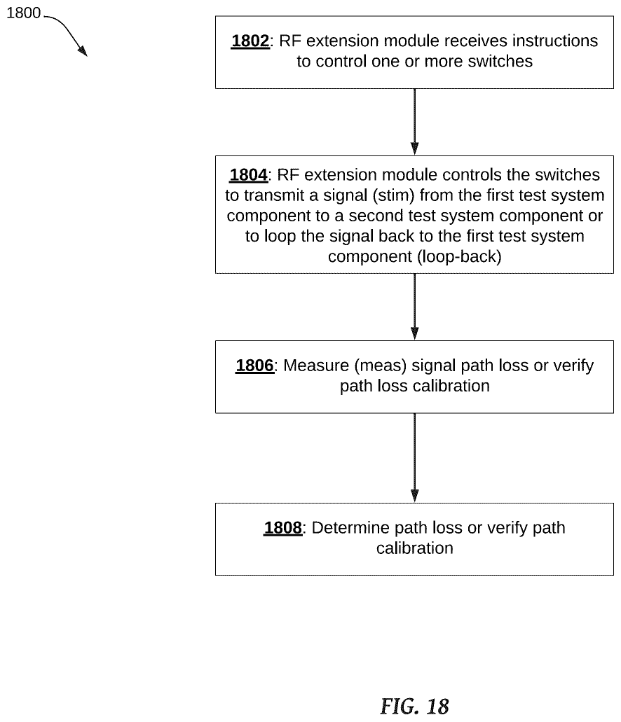

FIG. 18 is a flow chart depicting an exemplary sequence of computer-controlled steps of a process 1800 for automatically and selectively coupling bench instruments to characterize signal pathways of a test system according to embodiments of the present invention. The measurements taken during process 1800 can be used to de-embed test system components (e.g., cables, connectors, switches, etc.) and to verify path loss calibration to ensure accurate testing and measurements. Process 1800 can include validating compensation factors of test system components with a high degree of accuracy (e.g., within +/−1 dB).

At step 1802, an RF extension module (e.g., a FASTCO module) receives instructions to perform a hardware interface switching operating including controlling the operation of one or more switches thereof. For example, step 1802 can include receiving instructions at an ISM of the FASTCO module from a test system over an Ethernet connection for instance, and the ISM can control switches internal to the FASTCO module (e.g., switches disposed in the ISM or REM of the FASTCO module) to couple components of the test system.

At step 1804, the switch or switches of the FASTCO module is/are controlled to communicatively couple a first test system component with a second test system component. The test system components can be an ATE or ATS, a load board, or bench instruments, for example.

At step 1806, an RF signal (stim) is provided to the first test system component and a measurement is taken at the second test system component. Specifically, an ATE can be coupled to a bench instrument in step 1804, and step 1806 can include generating the stim using the bench instrument and measuring the RF signal using the ATE. In another example, the ATE is coupled to a load board in step 1804, and step 1806 includes the ATE generating the RF signal (stim), where the signal is then measured at the load board.

At step 1808, path loss can be calculated or an existing calibration (e.g., compensation factors) applied to mitigate path loss (e.g., de-embedding devices, connectors, cables, etc.) can be verified as described above according to embodiments.

According to some embodiments, step 1808 includes performing loop-back testing to characterize the signal pathway of components of the RF extension module. For example, step 1804 can include communicatively coupling the first test system component (e.g., an ATE or bench instrument) with itself using the switches of the RF extension module to loop an input RF signal generated by the first device back to the first device for measurement. More specifically, the signal can be looped though an REM of the RF extension module (e.g., to determine RFIM loss (FRL)), or through the REM and the ISM of the RF extension module (e.g., to determine ISM loss (FIL)), according to embodiments.

In sum, the disclosed techniques overcome the limitations of traditional methods by providing an automated, software controlled approach to selective device coupling that avoids the need for changing wires, connectors, or load boards to test devices using ATEs and bench equipment. Furthermore, the coupling can be controlled automatically by the test system without needing to manually change ports or adjust matrices by hand.

At least one technical advantage of the disclosed techniques is that pathloss can be mitigated more accurately and system components can be left in place while various components are used during device testing. One main advantage is that separate load boards are not required, which significantly reduces costs and testing complexity. Moreover, pathloss and be measured and compensated for more accurately using the correlation procedures described herein.

1. In some embodiments, an apparatus for selectively coupling devices of a test system, the apparatus comprises a plurality of switches, a communication port operable to receive control commands to control the plurality of switches to selectively couple devices of the test system, wherein a first set of the plurality of switches are communicatively coupled to a load board that receives devices under test (DUTs) for device testing.

2. The apparatus of clause 1, wherein an automated test equipment (ATE) is operable to control the plurality of switches via the communication port over a communication channel.

3. The apparatus of clause 2, wherein the first set of the plurality of switches are further operable to selectively couple a signal path from the load board to the ATE to perform device testing on the DUTs disposed on the load board according to a test program executed by the ATE.

4. The apparatus of clause 3, further comprising a microcontroller operable to receive the control commands over the communication channel and to control the plurality of switches according to the control commands.

5. The apparatus of clause 2 or 3, wherein the first set of the plurality of switches are further operable to selectively and communicatively couple the load board to a bench instrument operable to bench test the DUTs when the DUTs are disposed on the load board.

6. The apparatus of clause 3, wherein the communication port comprises Ethernet, and wherein the test program comprises a Java test program operable to access a library of external instrument drivers to control the bench instrument over Ethernet.

7. The apparatus of any clause 2 through 6, wherein the plurality of switches are operable to be controlled by a test program executed by the ATE, and wherein the test program accesses information that maps pogo pins of the ATE to port numbers to automatically couple components using the port numbers to control the plurality of switches.

8. The apparatus of any clause 2 through 7, wherein the plurality of switches are operable to provide a loop-back communication path for measuring path loss, and wherein the ATE is operable perform an automatic correlation procedure to correlate measurements of the ATE with measurements of bench instruments based on the path loss.

9. The apparatus of clause 8, wherein the ATE is further operable to automatically verify results of the automatic correlation procedure by coupling the ATE to the bench equipment using the plurality of switches and to receive an input RF signal generated by the bench equipment that is measured at the ATE.

10. In some embodiments, a test system for device testing comprises an automatic test equipment (ATE), a load board comprising a plurality of sockets, and a radio frequency (RF) extension module comprising a plurality of switches, wherein the RF extension module is operable to receive commands sent by the ATE to control operation of the plurality of switches to selectively couple the ATE to DUTs operable to be disposed in the plurality of sockets for device testing thereof.

11. The test system of clause 10, further comprising a bench instrument, wherein the RF extension module is further operable to control operation of the plurality of switches to selectively couple the DUTs to the bench instrument for testing the DUTs.

12. The test system of clause 10, further comprising a bench instrument, wherein the RF extension module is further operable to control operation of the plurality of switches to couple the ATE to the bench instrument for performing path loss calibration and verification operations.

13. The test system of clause 10, wherein the RF extension module is further operable to control the plurality of switches to provide a loop-back communication path for performing path loss calibration and verification operations of the RF extension module.

14. The test system of any clause 10 through 13, wherein the RF extension module further comprises an Ethernet interface, wherein the RF extension module is operable to receive commands over the Ethernet interface to control operations of the plurality of switches according to a test program that maps pins of the ATE to DUT ports coupled to the load board.

15. In some embodiments, a method of automatic hardware interface switching for device testing using a radio frequency (RF) extension module comprises receiving a command from an automated test equipment (ATE) to couple a first test system component with a second test system component, controlling operation of a plurality of switches of the RF extension module to couple the first test system component with the second test system component, generating an RF signal using the first test system component, automatically routing the RF signal to the second test system component via the plurality of switches, and measuring the RF signal at the second test system component.

16. The method of clause 15, wherein the first test system component comprises the ATE, and wherein the second test system component comprises a load board comprising a plurality of sockets operable to receive devices under test (DUTs) for device testing thereof by the ATE.

17. The method of clause 15, wherein the first test system component comprises the ATE and wherein the second test system component comprises a bench instrument.

18. The method of clause 17, wherein the ATE is operable to verify path loss calibration between the ATE and the bench instrument by measuring the RF signal generated by the bench instrument at the ATE.

19. The method of any clause 15 through 18, wherein the command from the ATE is received by a microcontroller of the RF extension module over Ethernet.

20. The method of clause 15, wherein the first test system component comprises a first device under test (DUT) component, wherein the second test system component comprises a second DUT component, and wherein controlling operation of a plurality of switches of the RF extension module to couple the first test system component with the second test system component comprises controlling operation of the plurality of switches to form a loop-back path operable to receive the RF signal from the first DUT component and loop the RF signal back for receipt by the second DUT component.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions. While the preceding is directed to embodiments of the present disclosure, other and further embodiments of the disclosure may be devised without departing from the basic scope thereof, and the scope thereof is determined by the claims that follow.

Embodiments of the present invention are thus described. While the present invention has been described in particular embodiments, it should be appreciated that the present invention should not be construed as limited by such embodiments, but rather construed according to the following claims.

What is claimed is:

1. An apparatus for selectively coupling devices of a test system, the apparatus comprising:
a plurality of switches;
a communication port operable to receive control commands to control the plurality of switches to selectively couple devices of the test system, wherein a first set of the plurality of switches are communicatively coupled to a load board for receiving devices under test (DUTs) for device testing, and wherein the DUTs are for testing by the test system via the first set of the plurality of switches.

2. The apparatus of claim 1, wherein an automated test equipment (ATE) is operable to control the plurality of switches via the communication port over a communication channel.

3. The apparatus of claim 2, wherein the first set of the plurality of switches are further operable to selectively couple a signal path from the load board to the ATE to perform device testing on the DUTs disposed on the load board according to a test program executed by the ATE.

4. The apparatus of claim 3, further comprising a microcontroller operable to receive the control commands over the communication channel and to control the plurality of switches according to the control commands.

5. The apparatus of claim 3, wherein the communication port comprises Ethernet, and wherein the test program comprises a Java test program operable to access a library of external instrument drivers to control the bench instrument over Ethernet.

6. The apparatus of claim 2, wherein the first set of the plurality of switches are further operable to selectively and communicatively couple the load board to a bench instrument operable to bench test the DUTs when the DUTs are disposed on the load board.

7. The apparatus of claim 2, wherein the plurality of switches are operable to be controlled by a test program executed by the ATE, and wherein the test program accesses information that maps pogo pins of the ATE to port numbers to automatically couple components using the port numbers to control the plurality of switches.

8. The apparatus of claim 2, wherein the plurality of switches are operable to provide a loop-back communication path for measuring path loss, and wherein the ATE is operable perform an automatic correlation procedure to correlate measurements of the ATE with measurements of a bench instrument based on the path loss.

9. The apparatus of claim 8, wherein the ATE is further operable to automatically verify results of the automatic correlation procedure by coupling the ATE to the bench instrument using the plurality of switches and to receive an input RF signal generated by the bench equipment that is measured at the ATE.

10. A test system for device testing, the system comprising:
an automatic test equipment (ATE);
a load board comprising a plurality of sockets; and
a radio frequency (RF) extension module comprising a plurality of switches, wherein the RF extension module is operable to receive commands sent by the ATE to control operation of the plurality of switches to selectively couple the ATE to DUTs operable to be disposed in the plurality of sockets for device testing thereof.

11. The test system of claim 10, further comprising a bench instrument, wherein the RF extension module is further operable to control operation of the plurality of switches to selectively couple the DUTs to the bench instrument for testing the DUTs.

12. The test system of claim 10, further comprising a bench instrument, wherein the RF extension module is further operable to control operation of the plurality of switches to couple the ATE to the bench instrument for performing path loss calibration and verification operations.

13. The test system of claim 10, wherein the RF extension module is further operable to control the plurality of switches to provide a loop-back communication path for performing path loss calibration and verification operations of the RF extension module.

14. The test system of claim 10, wherein the RF extension module further comprises an Ethernet interface, wherein the RF extension module is operable to receive commands over the Ethernet interface to control operations of the plurality of switches according to a test program that maps pins of the ATE to DUT ports coupled to the load board.

15. A method of automatic hardware interface switching for device testing using a radio frequency (RF) extension module, the method comprising:
receiving a command from an automated test equipment (ATE) to couple a first test system component with a second test system component;
controlling operation of a plurality of switches of the RF extension module to couple the first test system component with the second test system component;
generating an RF signal using the first test system component;
automatically routing the RF signal to the second test system component via the plurality of switches; and
measuring the RF signal at the second test system component.

16. The method of claim 15, wherein the first test system component comprises the ATE, and wherein the second test system component comprises a load board comprising a plurality of sockets operable to receive devices under test (DUTs) for device testing thereof by the ATE.

17. The method of claim 15, wherein the first test system component comprises the ATE and wherein the second test system component comprises a bench instrument.

18. The method of claim 17, wherein the ATE is operable to verify path loss calibration between the ATE and the bench instrument by measuring the RF signal generated by the bench instrument at the ATE.

19. The method of claim 15, wherein the command from the ATE is received by a microcontroller of the RF extension module over Ethernet.

20. The method of claim 15, wherein the first test system component comprises a first device under test (DUT) component, wherein the second test system component comprises a second DUT component, and wherein controlling operation of a plurality of switches of the RF extension module to couple the first test system component with the second test system component comprises controlling operation of the plurality of switches to form a loop-back path operable to receive the RF signal from the first DUT component and loop the RF signal back for receipt by the second DUT component.
